(19) United States
(12) Patent Application Publication
(10) Pub. No.: US 2021/0363011 A1
(43) Pub. Date: Nov. 25, 2021

(54) METHOD FOR PREPARING BORON NITRIDE NANOTUBES BY HEAT TREATING BORON PRECURSOR AND APPARATUS THEREOF

(71) Applicant: Naieel Technology, Daejeon (KR)

(72) Inventors: Jaewoo KIM, Daejeon (KR); Eun Kwang PARK, Daejeon (KR); Jae Hoon KIM, Daejeon (KR)

(21) Appl. No.: 17/070,675

(22) Filed: Oct. 14, 2020

(30) Foreign Application Priority Data
May 22, 2020 (KR) 10-2020-0061350

(51) Int. Cl. C01B 21/064; C23C 16/34; C23C 16/455

(52) U.S. Cl. CPC C01B 21/0641; C01P 2004/13; C23C 16/455; C23C 16/342

(57) ABSTRACT

The present disclosure provides a method for producing a boron nitride nanotube by heating a boron precursor, and an apparatus therefor. According to an embodiment, a method of producing a boron nitride nanotube includes: inserting several reaction modules each accommodating a holding rod disposed through at least one precursor block into a supply chamber disposed at a front end of a reaction chamber; conveying N reaction modules of the several reaction modules inserted in the supply chamber to a reaction zone of the reaction chamber; growing a boron nitride nanotube in the precursor block by operating the reaction zone for a predetermined time, in the reaction chamber; and conveying the N reaction modules from the reaction chamber to a discharge chamber disposed at a rear end of the reaction chamber after the predetermined time passes. Accordingly, it is possible to maximize the yield and productivity of BNNTs.

### CROSS-REFERENCE TO RELATED APPLICATIONS

This application claims the priority of Korean Patent Application No. 10-2020-0061350 filed on May 22, 2020, in the Korean Intellectual Property Office, the disclosure of which is incorporated herein by reference.

### BACKGROUND

### 1. Field

The present disclosure relates to a boron nitride nanotube. More particularly, the present disclosure relates to a method of producing a boron nitride nanotube by heating a boron precursor, and an apparatus therefor.

### 2. Description of the Related Art

Boron Nitride Nano-Tubes (BNNT) are similar in mechanical properties and thermal conduction to Carbon Nano-Tubes (CNT) well known in the art. However, a CNT has low thermal and chemical stability because it has conductors and semiconductors electrically mixed therein and oxidizes at about 400° C., but a BNNT has electrical insulation and is thermally stable even at high temperatures over about 800° C. even in the air because it has a wide band gap of about 5 eV. Further, boron in a BNNT has a thermal neutron absorption ability about 200 thousand times higher than carbon in a CNT, so it is a substance useful for blocking neutrons.

However, a BNNT requires a high-temperature synthesis process of 1000° C. or higher and has a limit in that it is difficult to increase the reaction yield due to impurities and/or remains that are produced in producing, and an expensive refining process is required to remove the impurities, so it is difficult to develop a technology that produces high-quality BNNTs in large quantities.

A technology about a method and apparatus for producing a BNNT that solve the problems described above has been recently developed (Korean Patent No. 10-1964432).

A technology that remarkably reduces the production time and the process energy and further increases the production yield of BNNTs has been required in relation to the method and apparatus for producing BNNTs in the industrial field with an increase in demand for BNNTs.

### SUMMARY

The present disclosure provides a method of producing a boron nitride nanotube by heating a boron precursor, and an apparatus therefor.

Firstly, it is to provide an apparatus and method of continuously supplying reaction modules to a reaction chamber through a continuous organic operation of a supply chamber, a reaction chamber, and a discharge chamber in relation to an apparatus and method of producing a boron nitride nanotube.

Secondly, it is to provide an apparatus and method being able to uniformly compound, mix, and supply a reaction gas through arrangement of reaction gas supply pipes and supply holes.

A method of producing a boron nitride nanotube according to an embodiment of the present disclosure includes steps of: inserting several reaction modules each accommodating a holding rod disposed through at least one precursor block into a supply chamber disposed at a front end of a reaction chamber; conveying a first set of N reaction modules of the several reaction modules inserted in the supply chamber to a reaction zone of the reaction chamber; growing a boron nitride nanotube in the precursor block by operating the reaction zone for a predetermined time, in the reaction chamber; and conveying the first set of N reaction modules from the reaction chamber to a discharge chamber disposed at a rear end of the reaction chamber after the predetermined time passes, in which the conveying of the first set of N reaction modules of the several reaction modules inserted in the supply chamber to a reaction zone of the reaction chamber conveys a second set of N reaction modules of the several reaction modules from the supply chamber to the reaction chamber when conveying the first set of N reaction modules from the reaction chamber to the discharge chamber, and a conveying operation of the supply chamber may be ended when all the several reaction modules are conveyed to the reaction chamber.

The conveying the first set of N reaction modules of the several reaction modules inserted in the supply chamber to a reaction zone of the reaction chamber may be accomplished by moving up the several reaction modules, which are vertically arranged, in the supply chamber in a longitudinal direction of the supply chamber.

The conveying the first set of N reaction modules of the several reaction modules inserted in the supply chamber to the reaction zone of the reaction chamber may be accomplished by circulating several reaction modules arranged on a circulation track along the circulation track in the supply chamber.

A method of producing a boron nitride nanotube according to an embodiment of the present disclosure includes steps of: conveying a reaction module accommodating a holding rod disposed through at least one precursor block to a reaction zone of a reaction chamber; and growing a boron nitride nanotube by reacting a nitrogen-containing reaction gas supplied from two or more gas supply pipes disposed in the reaction chamber with the precursor block, in which a gas supply hole that is diagonally open may be formed on a surface of each of the gas supply pipes.

An even number of gas supply pipes maybe disposed in a pair at positions facing each other in the diameter direction of the reaction chamber, and the gas supply holes of a pair of the gas supply pipes may be open in opposite directions.

The gas supply holes may be formed to be alternate to each other on the gas supply pipes.

Each of the gas supply holes may be formed on each of the gas supply pipes and may be disposed with regular intervals in a longitudinal direction of the gas supply pipes in the reaction zone.

An apparatus for producing a boron nitride nanotube according to another embodiment of the present disclosure includes: a reaction module accommodating a holding rod disposed through at least one precursor block; a reaction chamber having a conveying path for conveying the reaction module and a reaction zone in which a nitrogen-containing reaction gas is provided to the precursor block on the conveying path; a supply chamber disposed at a front end of the reaction chamber, accommodating several reaction modules, and conveying a first set of N reaction modules of the several reaction modules to the reaction chamber; and a discharge chamber disposed at a rear end of the reaction chamber, in which the reaction chamber conveys the first set of N reaction modules to the discharge chamber, and the supply chamber conveys a second set of N reaction modules of the several reaction modules to the reaction chamber when the first set of N reaction modules are conveyed from the reaction chamber to the discharge chamber, and a conveying operation of the supply chamber may be ended when all the several reaction modules are conveyed to the reaction chamber.

The supply chamber may include a lift having a plurality of reaction module holding units vertically arranged to mount the several reaction modules, and moving up the plurality of reaction module holding units in a longitudinal direction of the supply chamber.

The supply chamber may include a lift having a plurality of reaction module holding units arranged on a circulation track to mount the several reaction modules, and circulating the plurality of reaction module holding units along the circulation track.

An apparatus for producing a boron nitride nanotube according to another embodiment of the present disclosure includes: a reaction module accommodating a holding rod disposed through at least one precursor block; a reaction chamber having a conveying path for conveying one or more of the reaction modules and a reaction zone in which a nitrogen-containing reaction gas is provided to the precursor block on the conveying path; and at least two gas supply pipes disposed along the conveying path, in which one or more gas supply holes that are diagonally open are formed on a surface of each of the gas supply pipes.

The several reaction modules each may include: a pair of supports separably combined with the holding rod, having holders formed at positions respectively corresponding to the gas supply pipes, and facing each other; and a housing formed between the pair of supports to accommodate the holding rod.

An even number of gas supply pipes may be disposed in a pair at positions facing each other in the diameter direction of the reaction chamber, and the gas supply holes of the pair of gas supply pipes may be open in opposite directions.

The gas supply holes may be formed to be alternate to each other on the gas supply pipes.

Each of the gas supply holes may be formed on each of the gas supply pipes and may be disposed with regular intervals in a longitudinal direction of the gas supply pipes in the reaction zone.

According to the present disclosure, there are the following effects.

First, in an organic continuous process continuing through the supply chamber, the reaction chamber, and the discharge chamber, reaction modules are continuously supplied to the reaction chamber, thereby being able to maximize the yield and productivity of BNNTs.

Second, since the reaction gas supply pipes and supply holes are disposed, a reaction gas supplied to the reaction chamber may be compounded by a vortex generated by turning of the reaction gas, thereby being able to maximize the yield and productivity of BNNTs.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a flowchart schematically showing a method of producing a boron nitride nanotube according to an embodiment of the present disclosure;

FIG. 2 is a flowchart schematically showing a method of producing a boron nitride nanotube according to another embodiment of the present disclosure;

FIG. 3 is a plan view schematically showing an apparatus for producing a boron nitride nanotube according to still another embodiment of the present disclosure;

FIG. 4A is a vertical cross-sectional view schematically showing the apparatus for producing a boron nitride nanotube according to still another embodiment of the present disclosure;

FIG. 4B is a vertical cross-sectional view schematically showing the apparatus for producing a boron nitride nanotube according to still another embodiment of the present disclosure;

FIG. 5 is a perspective view schematically showing an embodiment of a reaction module of the present disclosure;

FIG. 6 is a plan view schematically showing an embodiment of a reaction module of the present disclosure;

FIG. 7A is a plan view showing a precursor block according to a embodiment of the present disclosure; FIG. 7B is a plan view showing a precursor block according to another embodiment of the present disclosure;

FIG. 8A is a cross-sectional view schematically showing embodiments of a reaction chamber and a gas supply pipe of the present disclosure;

FIG. 8B is a cross-sectional view schematically showing embodiments of a reaction chamber and a gas supply pipe of the present disclosure;

FIG. 9A is a cross-sectional view schematically showing an embodiment of a reaction chamber and a gas supply pipe of the present disclosure;

FIG. 9B is a cross-sectional view schematically showing an embodiment of a reaction chamber and a gas supply pipe of the present disclosure;

FIG. 10A is a side view schematically showing an embodiment of a gas supply pipe of the present disclosure; and

FIG. 10B is a side view schematically showing an embodiment of a gas supply pipe of the present disclosure.

### DETAILED DESCRIPTION OF THE PREFERRED EMBODIMENT

Example embodiments of the present disclosure will be described in detail but technological configurations well known in the art are omitted or compressed for brief description.

Hereinafter, embodiments of the present disclosure are described in detail with reference to the accompanying drawings, and in the following description of the accompanying drawings, like reference numerals are given to like components and repetitive description is omitted.

In the following embodiments, terms such as “first” and “second” are used to discriminate a component from another component without limiting the components.

When an embodiment can be implemented in another way, specific processes may be performed in order different from the description. For example, two sequentially described processes may be substantially simultaneously performed or may be performed in the reverse order of the described order.

### Description of Precursor Block for Producing Boron Nitride Nanotube

A precursor block for producing a boron nitride nanotube of the present disclosure is manufactured by an apparatus for manufacturing a precursor block.

The apparatus for manufacturing a precursor block forms a precursor block by mixing a binder in powder including boron.

Firstly, the powder may include first powder and second powder.

The first powder may include boron.

The boron may be in a powder state.

The boron may be amorphous and/or crystalline boron.

Since amorphous boron has low hardness, the amorphous boron efficiently contributes to nano-sizing of the particles of catalytic metal and a metal oxide that are additionally mixed in a nano-sizing step, in detail, a nano-sizing process of boron powder using vortexes of air. Further, nano-sized boron is coated on or embedded in the surfaces of the nanoparticles of the catalytic metal and the metal oxide, whereby seed precursor nanoparticles with high efficiency may be obtained. On the other hand, when crystalline boron is used, nano-sizing may be difficult and may take a long time due to high hardness, so a composition yield may be deteriorated or the entire process may take a long time when producing a BNNT, which may reduce productivity. Using crystalline born consequently causes deterioration of the purity of a BNNT, and an additional precise refining process is also required to reduce impurities, which may cause an increase in the producing cost.

Therefore, according to an embodiment of the present disclosure, the boron may be amorphous boron rather than crystalline boron. When amorphous boron is used, it is possible to obtain boron nanopowders even through a short nano-sizing process. Further, it is possible to form a BNNT at a high yield.

The first powder may further include a catalyst and the catalyst may be provided in a powder state. The catalyst is more effective for amorphous boron. This is because it is possible to produce a large amount of boron nanopowders within a very short time when using amorphous boron unlike using crystalline boron in a nano-sizing process that uses air jets and/or vortexes of air. The catalyst is mixed with boron particles in a nano-sizing process of the first powder, thereby producing precursor nanoparticles. The precursor nanoparticles function as seeds and react with nitrogen in producing of a BNNT, thereby being able to contribute to composition of a BNNT. The catalyst particles are not specifically limited, and for example, may be Fe, Mg, Ni, Cr, Co, Zr, Mo, W, and/or Ti, and oxides thereof.

Forming a precursor block 2 is described in detail.

According to an embodiment of the present disclosure, second powder including a boron precursor is produced through nano-sizing of first powder in which precursor boron powder and catalyst powder are mixed.

In nano-sizing of the first powder, first air may be provided at an angle to a normal direction of a circular nano-sizing area and the first powder may be provided at an acute angle to the flow direction of the first air.

The nano-sizing area, which is positioned inside a container that is a component of a first-powder nano-sizing apparatus, may be an area where second powder is produced through nano-sizing of the first powder.

The container may have a nano-sizing area, a first inlet, a second inlet, and an outlet.

The nano-sizing area may be defined as a circle, and accordingly, the first air flowing inside through the second inlet of the first-powder nano-sizing apparatus may generate a vortex in the nano-sizing area.

The first powder may be made into a nano-size by the first air rotating at a highspeed in the nano-sizing area. Boron powder and catalyst powder may be mixed in the first powder, as described above, and the boron powder may be embedded with an optimal amount of catalyst powder by nano-sizing in the nano-sizing area, whereby an optimal condition and/or particle size for composition and growth of a BNNT to be described above may be provided.

As described above, second powder may be produced by the first air in the nano-sizing area.

Thereafter, second air is sent through a first membrane connected with the nano-sizing area such that the second air collects in a first collection container accommodating the first membrane.

The second air is sent through a second membrane from the first collection container and the second powder is put into a receiver connected with the second membrane, thereby being able to collect the second powder included in the second air.

A binder including at least one of sucrose, syrup, glutinous starch syrup, polypropylene carbonate, polyvinyl alcohol, polyvinyl butyral, and ethyl cellulose, which may be sublimated and removed in a gas state in a high-temperature heat treatment BNNT composition process to be described below, with precursor powder in the collected second powder, thereby forming the precursor block 2. However, the binder may be removed in a sublimation process and may leave a smallest amount of remains in the precursor block, and any substance may be used as the binder as long as it may form pores in the block.

Meanwhile, the second powder may include large-granularity catalyst particles not made into a nano-size in the nano-sizing process and/or not filtered in the collecting process.

The large-granularity catalyst particles may act as an impurity in a finally obtained BNNT and may decrease the purity. Accordingly, it is preferable to remove particles having a diameter over 1000 nm and a refining process of removing such large-granularity catalyst particles may be included.

The precursor block 2 maybe formed in a removable film shape such as a release film. It is possible to manufacture a precursor block 2 having a predetermined shape, for example, by putting a release film into a mold, uniformly spreading a powder mixture of precursor powder and binder powder on the release film, and then pressing the powder mixture. Preferably, it is possible to put the precursor block 2 into a heat treatment reaction chamber after removing the release film.

In this case, the binder may be used not only in a powder state, but also in a liquid state.

When the binder is used in a powder state, the precursor block 2 is manufactured by producing a powder mixture by mixing the precursor powder and the binder powder and then uniformly spreading and heating the powder mixture at an appropriate temperature. Alternatively, the precursor block 2 may be manufactured by uniformly spreading the powder mixture in a mold, which may manufacture a block having a predetermined shape, and pressing the powder mixture with a hot-press at a predetermined temperature such that the viscosity of the binder powder increases and accordingly the precursor powder is bonded to each other.

When the binder is in a liquid state, it is possible to simply form a block by mixing precursor powder in the liquid binder, uniformly spreading the mixture on a release film, and then heating and drying the mixture at an appropriate temperature.

In this case, any binders such as sucrose, syrup, glutinous starch syrup, or polyvinyl alcohol (PVA) may be used as the liquid binder by mixing them in water.

Further, binders such as polypropylene carbonate (PPC), polyvinyl butyral (PVB), or ethyl cellulose (EC) may be used as liquid binders by using a solvent. In this case, the solvent may be appropriately selected, depending on the kinds of binders. For example, ketone or ethyl acetate may be used for polypropylene carbonate (PPC), methanol or ethanol may be used for polyvinyl butyral (PVB), and terpinol may be used for ethyl cellulose (EC).

According to another embodiment, it is possible to form a precursor block 2 by applying and spreading a mixture of precursor powder and a binder on a predetermined substrate and then pressing or heating the mixture, and it is possible to put the substrate with the precursor block 2 formed thereon into a reaction chamber. In this case, the precursor block 2 may be formed not only on a surface, but also both surfaces of the substrate. When a block is formed by applying a mixture on a substrate, the above-mentioned method of forming a block on a release film may be applied as it is.

In this case, it is preferable to use a substrate made of a material that may resist heat treatment at a high temperature because the mixture may be put into a reaction chamber 31 together with the substrate. Accordingly, the substrate may be made of metal such as stainless steel (STS), tungsten (W), and titanium (Ti), an oxide of the metal, and ceramic such as silicon carbide (SiC) and alumina.

Considering reaction efficiency with nitrogen in the reaction chamber, it is preferable that the precursor block 2 is thin, but it may be thick in consideration of shape stability that maintains the shape of the block in the reaction chamber. In particular, the binder used for manufacturing the precursor block 2 is sublimated in the heat treatment process, thereby forming a plurality of pores in the precursor block 2 during the heat treatment.

For example, when sucrose is used as the binder, the pores may be formed through a thermal decomposition process expressed as the following chemical formula (Formula 1), and carbon that is produced as a remain may maintain the soundness of the precursor block throughout the BNNT composition process by functioning as a support for the porous precursor block.

C12H22O11 (Surcrose)+heat→12C+11H₂O

A BNNT is produced by applying heat treatment to the precursor block 2 formed in this way. A method of producing a BNNT is described hereafter.

### Description of Method of Producing BNNT

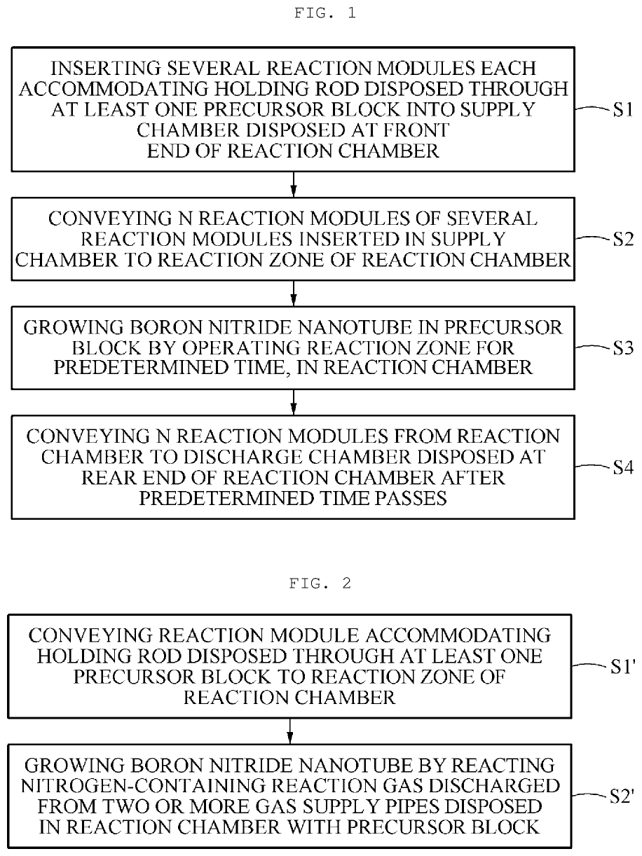

FIG. 1 is a flowchart schematically showing a method of producing a boron nitride nanotube according to an embodiment of the present disclosure.

In briefly, a BNNT may be grown by providing a reaction gas to a heated reaction zone while moving the precursor block 2 to the reaction zone in a reaction chamber.

Referring to FIG. 1, a method of producing a boron nitride nanotube (BNNT) according to an embodiment of the present disclosure includes inserting several reaction modules each accommodating a holding rod 37 disposed through at least one precursor block 2 into a supply chamber 321 disposed at the front end of a reaction chamber 31 (S1); conveying N reaction modules of the several reaction modules inserted in the supply chamber 321 to a reaction zone 311 of the reaction chamber 31 (S2); growing a BNNT in the precursor block 2 by operating the reaction zone 311 for a predetermined time (S3), in the reaction chamber 31; and conveying the N reaction modules from the reaction chamber 31 to a discharge chamber 322 disposed at the rear end of the reaction chamber 31 after the predetermined time passes (S4).

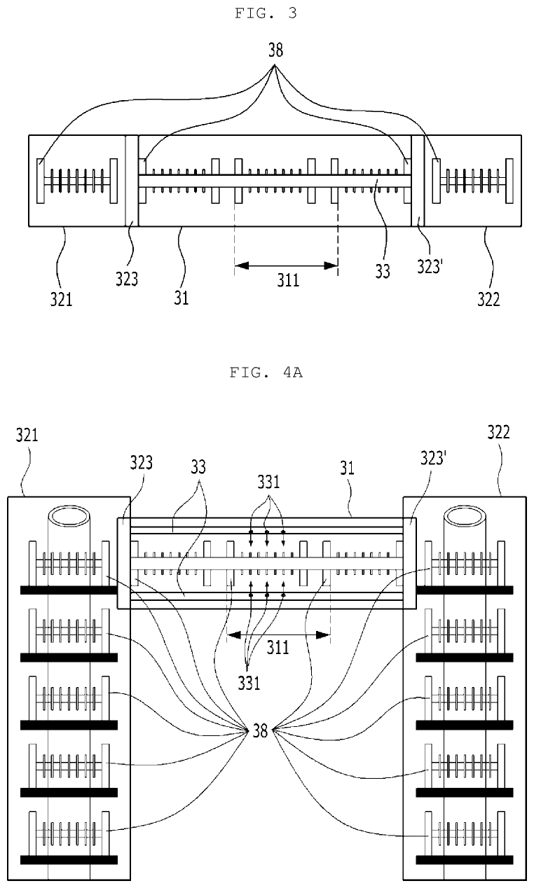

FIG. 2 is a flowchart schematically showing a method of producing a boron nitride nanotube (BNNT) according to another embodiment of the present disclosure.

As shown in FIG. 2, a method of producing a BNNT according to another embodiment includes conveying a reaction module 38 accommodating a holding rod 37 disposed through at least one precursor block 2 to a reaction zone 311 of a reaction chamber 31 (S1′); and growing a BNNT by reacting a nitrogen-containing reaction gas discharged from two or more gas supply pipes 33 disposed in the reaction chamber 31 with the precursor block 2 (S2′).

An embodiment of a method of producing a boron nitride nanotube is described in detail hereafter.

As shown in FIGS. 3, 4A, 4B, and 6, an apparatus 3 for producing a boron nitride nanotube that performs the method of producing a boron nitride nanotube according to an embodiment of the present disclosure includes a reaction chamber 31, a supply chamber 321, a discharge chamber 322, and a reaction module 38.

The reaction chamber 31 is used to accommodate the precursor block 2 described above, a conveying path for conveying the reaction module 38 is formed in the reaction chamber 31, and a reaction zone in which a BNNT is grown by providing a nitrogen-containing reaction gas to the precursor block 2 is included in a part of the conveying path.

The reaction zone 311 is an area in which an appropriate temperature for reaction is maintained and a reaction gas is provided through the gas supply pipes 33.

The reaction gas for producing a BNNT from the precursor block 2 disposed in the reaction chamber 31 may be a nitrogen-containing reaction gas. In detail, the reaction gas that is supplied into the reaction chamber 31 is not specifically limited, nitrogen (N₂) or ammonia (NH₃) may be used, and these gases may be mixed and supplied into the reaction chamber 31 as a gas mixture. Alternatively, hydrogen (H₂) may be additionally mixed and used.

The reaction gas may be supplied at a speed of 20 to 500 sccm into the reaction chamber 31. When the reaction gas is supplied at a speed less than 20 sccm, the supply amount of the nitrogen element is small, so the nitrification reaction efficiency of boron is deteriorated and reaction needs to be performed for a long time. When the speed exceeds 500 sccm, the boron powder in the solid precursor block 2 is ablated due to the high movement speed of the reaction gas, so the yield of BNNTs may decrease.

A BNNT may be obtained by performing heat treatment in the temperature range of about 1100 to about 1400° C. for approximately 0.5 to 6 hours in the reaction chamber 31.

The reaction chamber 31 may be an alumina pipe, but is not necessarily limited thereto and may be made of a material that may resist a temperature of up to about 1500° C.

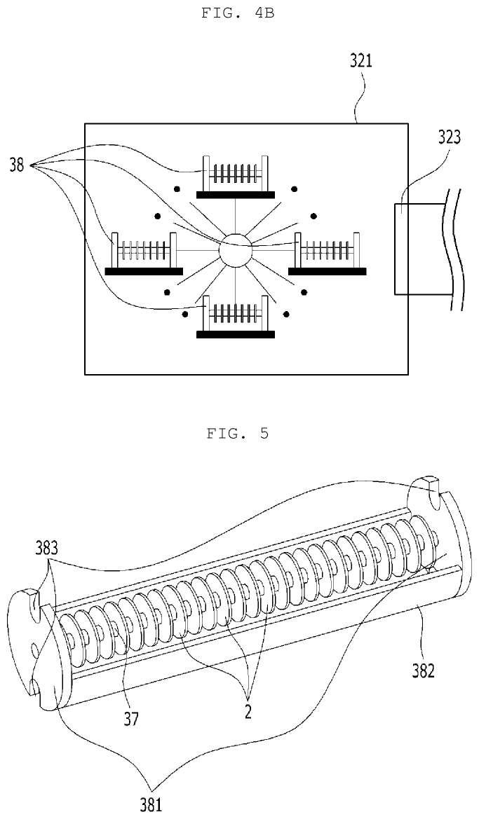

As depicted in FIG. 4A, the supply chamber 321 and the discharge chamber 322 may be connected to a front end and a rear end of the reaction chamber 31 respectively, and a front gate 323 and a rear gate 323′ may be disposed between the reaction chamber 31 and the supply chamber 321 and between the reaction chamber 31 and the discharge chamber 322 respectively, whereby it is possible to separate the environments inside of the chambers.

A vacuum device (not shown) is connected with the reaction chamber 31 and may adjust the degree of a vacuum in the reaction chamber 31, and to this end, the vacuum device may include a vacuum pump and a controller. However, the present disclosure is not necessarily limited thereto. For example, the vacuum device may be connected to the supply chamber 321, or the vacuum device may be connected to the discharge chamber 322.

A temperature adjuster (not shown) may be connected to the reaction chamber 31. The temperature adjuster (not shown) may include a heater directly adjusting the temperature in the reaction chamber 31 and a controller controlling the heater.

The supply chamber 321 is disposed at the front end of the reaction chamber 31. The supply chamber 321 accommodates several reaction modules and N reaction modules of the several reaction modules are conveyed to the reaction chamber 31. A pusher for pushing the reaction modules 38 maybe disposed in the supply chamber 321. The reaction modules in the supply chamber 321 may be pushed into the reaction chamber 31.

The discharge chamber 322 is disposed at the rear end of the reaction chamber 31. The discharge chamber 322 receives the N reaction module from the reaction chamber 31.

The supply chamber 321, the reaction chamber 31, and the discharge chamber 322 may be organically operated to continuously put the reaction modules 38 into the reaction chamber 31.

In detail, when N reaction modules are conveyed to the discharge chamber 322 from the reaction chamber 31 to continuously supply N reaction modules to the reaction chamber 31, the supply chamber 321 conveys N new reaction modules of the several reaction modules to the reaction chamber 31.

When the several reaction modules accommodated in the supply chamber 321 are all conveyed into the reaction chamber 31 through this process, the supply chamber 321 stops operating without conveying a reaction module 38 to the reaction chamber 31.

As shown in FIGS. 4A and 4B, the supply chamber 321 may have various types of lifts for continuously supplying several reaction modules to the reaction chamber 31.

For example, as shown in FIG. 4A, when several reaction modules are vertically accommodated in the supply chamber 321, a plurality of reaction module holding units for mounting the several reaction modules may be vertically arranged in the supply chamber 321. A reaction module 38 is mounted on each of the plurality of reaction module holding units and the several reaction modules may be moved up in the longitudinal direction of the supply chamber 321 in the supply chamber 321 by the lift.

Alternatively, as shown in FIG. 4B, several reaction modules maybe arranged on a circulation track in the supply chamber 321. In this case, a plurality of reaction module holding units for mounting the several reaction modules may be arranged on the circulation track in the supply chamber 321, and the reaction modules 38 mounted on each of the plurality of reaction module holding units may be circulated along the circulation track by a lift.

A controller for controlling the organic operation of the supply chamber 321, the reaction chamber 31, and the discharge chamber 322 may be provided.

Hereafter, a process of continuously putting reaction modules 38 into the reaction chamber 31 is described.

Firstly, the temperature and the gas atmosphere in the reaction chamber 31 are optimized, and then a reaction module 38 having a precursor block is put into the reaction chamber 31 through the supply chamber 321. Since the front gate 323 is disposed between the supply chamber 321 and the reaction chamber 31, it is possible to put the reaction module 38 into the reaction chamber 31 while maximally maintaining the atmosphere in the reaction chamber 31.

A front gate 323 and a vacuum pump may be additionally disposed in the supply chamber 321 together with the above-mentioned lift that may convey reaction modules 38 toward the reaction chamber 31. Accordingly, when the front gate 323 of the reaction chamber 31 is opened, the reaction gas atmospheres and pressures of the supply chamber 321 and the reaction chamber 31 may become equilibrium respectively, and a reaction module 38 is conveyed to the reaction chamber 31 from the supply chamber 321. Further, the gate front 323 is closed after the reaction module 38 is conveyed.

When the front gate 323 is closed, an auxiliary gate of the supply chamber 321 is opened again, a new reaction module 38 is put into the supply chamber 321, the gate is closed, and then the reaction module 38 is conveyed into the reaction chamber 31 through the process described above. In this operation, the auxiliary gate and the vacuum pump prevent the block precursor of a reaction module in the supply chamber 321 from being contaminated and make the inside of the supply chamber 321 similar to the atmosphere of the reaction chamber 31.

Reaction modules 38 are sequentially conveyed toward the discharge chamber 322 in this way, so the reaction modules 38 may be horizontally sequentially arranged in the reaction chamber 31.

The reaction chamber 31 performs a process of growing a BNNT in a precursor block by providing a reaction gas to the reaction module disposed in a reaction zone 311 by operating the reaction zone 311 for a predetermined time.

The supply amount of the reaction gas may be adjusted in this process to maintain maximum reaction with the reaction gas when a reaction module 38 is positioned at the center of the reaction zone 311.

Such a sequential operation may be applied as follows when there is a storage space for storing one or more reaction modules in the supply chamber 321.

A conveyer that may continuously convey reaction modules 38 toward the reaction chamber 31 from the storage space of the supply chamber 321 may convey reaction modules 38 in the supply chamber 321 toward the front end of the reaction chamber 31 in the longitudinal direction of the supply chamber 321 while supporting the reaction modules 38.

Accordingly, since one or more reaction modules 38 may be stored in the supply chamber 321, it is not required to individually put a new reaction module 38 into the auxiliary gate of the supply chamber 321 every time a reaction module 38 is conveyed into the reaction chamber 31.

Thereafter, the front gate 323 disposed between the supply chamber 321 and the reaction chamber 31 is opened when a reaction module 38 is conveyed toward the front end of the reaction chamber 31 by the conveyer 3211.

The front gate 323 disposed between the supply chamber 321 and the reaction chamber 31 is closed when the reaction module 38 is conveyed into the reaction chamber 31 by the conveyer.

However, preferably, the front gate 323 disposed between the supply chamber 321 and the reaction chamber 31 is closed after a predetermined number of reaction modules 38 that the reaction chamber 31 may accommodate are continuously conveyed into the reaction chamber 31 from the supply chamber 321.

Accordingly, one or more reaction modules 38 may be put into the reaction chamber 31 and may react with the reaction gas therein.

Meanwhile, the discharge chamber 322 may discharge reaction modules 38 from the reaction chamber 31 by reversely performing the operation of conveying reaction modules 38 from the supply chamber 321 to the reaction chamber 31.

Though not shown in the figures, the rear gate 323′ and the vacuum pump may be additionally disposed in the discharge chamber 322 together with a separate conveyer that may discharge reaction modules 38 from the reaction chamber 31. Accordingly, when the rear gate 323′ between the reaction chamber 31 and the discharge chamber 322 is opened, the reaction gas atmospheres and pressures of the discharge chamber 322 and the reaction chamber 31 may become equilibrium respectively, and a reaction module 38 is conveyed into the discharge chamber 322. Further, the rear gate 323′ is closed after the reaction module 38 is conveyed.

When the rear gate 323′ is closed, an auxiliary gate of the discharge chamber 322 is opened, a reaction module 38 that has finished reacting is taken out, and then the auxiliary gate is closed. Reaction modules 38 that have finished reacting are discharged from the reaction chamber 31 through this process. In this operation, the discharge chamber 322 changes into a nitrogen atmosphere similar to the atmosphere using the vacuum pump before the auxiliary gate is opened. Accordingly, after a reaction module 38 is discharged, precursor blocks in the reaction chamber 31 are prevented from being contaminated before the rear gate 323′ is opened, and the inside of the discharge chamber 322 is made similar to the atmosphere of the reaction chamber 31.

Reaction modules 38 that have finished reacting may be sequentially discharged outside in this way.

Thereafter, the rear gate 323′ is opened and a reaction module 38 is moved to the discharge chamber 322. The reaction module 38 may be discharged from the discharge chamber 322 after the rear gate 323 is closed.

Such a sequential operation may be applied as follows when there is a storage space for storing one or more reaction modules in the discharge chamber 322.

A conveyer that may continuously convey reaction modules 38 that have finished reacting from the reaction chamber 31 toward a storage space of the discharge chamber 322 may convey reaction modules 38 in the discharge chamber 322 toward the auxiliary gate of the discharge chamber 322 in the longitudinal direction of the discharge chamber 322 while supporting the reaction modules 38.

Accordingly, since one or more reaction modules 38 may be stored in the discharge chamber 322, it is not required to individually take out the reaction modules 38 that have finished reaction through the auxiliary gate of the discharge chamber 322 every time a reaction module 38 is conveyed into the reaction chamber 31.

Thereafter, the rear gate 323′ disposed between the discharge chamber 322 and the reaction chamber 31 is opened when a reaction module 38 is conveyed toward the rear end of the reaction chamber 31 by the conveyer.

Thereafter, the rear gate 323′ disposed between the discharge chamber 322 and the reaction chamber 31 is closed when a reaction module 38 is conveyed into the reaction chamber 31.

However, preferably, the rear gate 323′ disposed between the discharge chamber 322 and the reaction chamber 31 may be closed after a predetermined number of reaction modules 38 such that the reaction chamber 31 may accommodate are continuously conveyed into the reaction chamber 31 from the supply chamber 321.

When a BNNT is grown by applying heat treatment to powder in accordance with a conventional method, a process of temperature increase, maintaining temperature maintenance, BN composition, BNNT growth, temperature decrease, room temperature cooling, and reactant collection has to be undergone. Thus, there is a limit in one-time output, and it is difficult to minimize cost due to an increase in energy and time.

However, according to an embodiment of the present disclosure, since BNNTs are continuously produced in a line by the method described above, it is possible to maximize the yield and productivity of BNNTs.

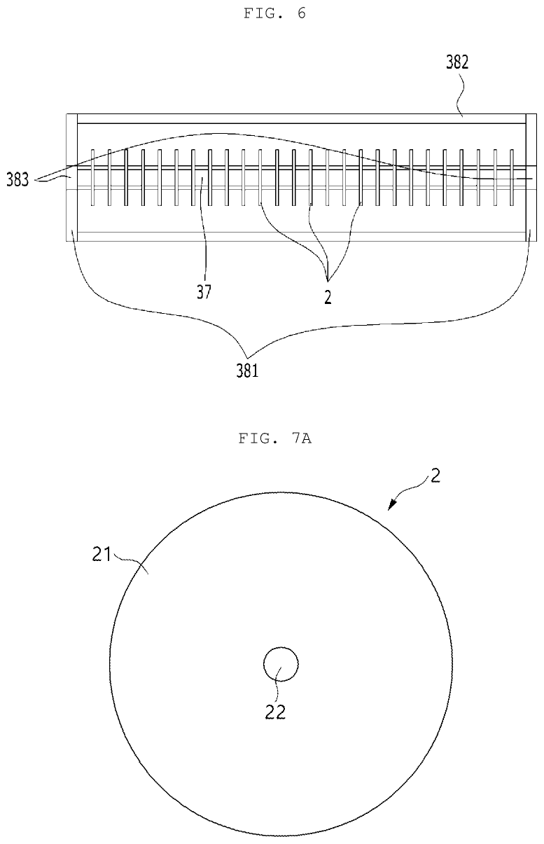

The above-described precursor blocks 2 may be arranged in the reaction chamber 31, that is, as shown in FIGS. 5 and 6, a holding rod 37 is disposed through at least one precursor block 2 and then puts into at least the reaction zone 311 in the reaction chamber 31. The holding rod 37 may be disposed in parallel with the longitudinal direction of the reaction chamber 31.

According to an embodiment of the present disclosure, a reaction module 38 may be provided to accommodate the precursor blocks 2.

The holding rod 37 disposed through at least one precursor block 2 is accommodated in the reaction module 38.

That is, as shown in FIGS. 5 and 6, precursor blocks 2 may be accommodated in a reaction module 38 and such reaction modules 38 may be continuously supplied into the reaction chamber 31, as shown in FIGS. 3, 4A, and 4B.

As shown in FIGS. 5 and 6, the reaction module 38 has a pair of supports 381 facing each other and a housing 382 having a storage space, in which the holding rod 37 is disposed, between the supports 381. The holding rod 37 maybe coupled to the supports 381. The holding rod 37 may be disposed through holes formed in the supports 381 so that the support 381 and the holding rod 37 may be separately combined, and precursor blocks 2 maybe arranged on the holding rod 37, as described above. The supports 381 may be made of alumina that is a heat-proof material but is not necessarily limited thereto.

Though not shown in the figures, one or more holes may be formed in the supports 381. The pressure of a reaction gas in the reaction module 38 may be prevented from being maintained at an excessive level due to the supports 381 and the pressure of a reaction gas in the reaction chamber 31 may be appropriately maintained by the holes. The holes are formed in the pair of supports 381 to correspond each other, whereby a reaction gas may uniformly and smoothly flow to both sides.

According to an embodiment of the present disclosure, as described above, since at least one precursor block 2 is disposed on the holding rod 37, it is possible to compose and grow a BNNT using the at least one precursor block 2. Accordingly, the reaction space in the reaction chamber 31 may be maximally used, productivity and/or mass productivity may be maximized.

Precursor blocks 2 may be disposed with predetermined gaps on the holding rod 37 and it is possible to adjust the number of blocks that is put into the reaction chamber 31 by adjusting the gaps of the precursor blocks 2.

At least one notch (not shown) may be formed on the holding rod 37 so that a precursor block 2 may be fixed on the holding rod 37 by the notch (not shown). Accordingly, it is possible to adjust the gaps and/or the number of precursor blocks to be mounted by adjusting gaps of the notches (not shown).

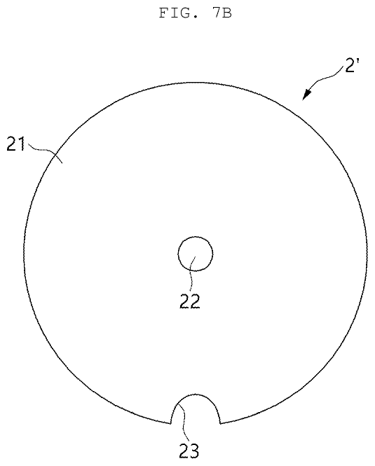

Meanwhile, the precursor block 2 may be formed to corresponding to the shape of the space in the reaction chamber 31. That is, when the inside of the reaction chamber 31 is a circle, a circular block body 21 may be provided as shown in FIG. 7A. A holding hole 22 is formed at the center of the block body 21 so that the holding rod 37 may be disposed through the holding hole 22.

In the meantime, the diameter of the block body 21 of the precursor block 2 may be formed smaller than the inner diameter of the reaction chamber 31.

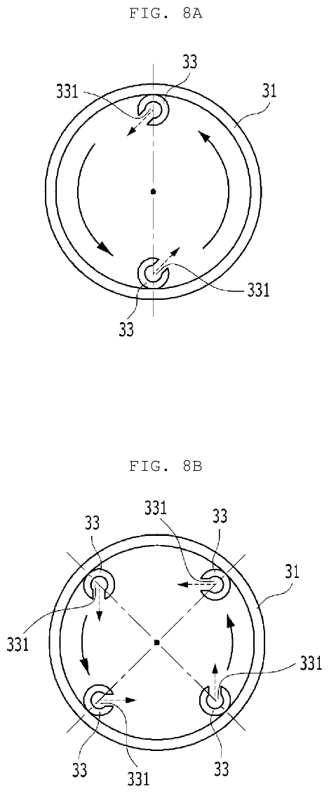

A precursor block 2′ according to another embodiment shown in FIG. 7B may further have a groove 23 formed on a side of the block body 21. When a gas supply pipe 33 (illustrated in FIG. 8A) is disposed at a side in the reaction chamber 31, interference between the block body 21 and the gas supply pipe 33 may be prevented by the groove 23.

As shown in FIG. 7A, precursor block 2 may be disposed in the reaction chamber such that a reaction gas comes in contact with the precursor block 2 as much as possible. For example, the precursor block 2 may be disposed vertically in a horizontal cylindrical reaction chamber, that is, perpendicular to the bottom of the reaction chamber. Since the precursor block 2 is vertically disposed, a plurality of precursor block 2 may be arranged in the reaction chamber, which is preferable because BNNTs may be manufactured in large quantities through one-time heat treatment process. Further, since the precursor block 2 is formed in a thin film shape, a nitrogen-containing reaction gas may come in contact with both sides of the precursor block 2. Accordingly, the reaction area increases, and the yield of BNNTs may be improved.

Vertically disposing the precursor block 2 in the horizontal cylindrical reaction chamber 31 may be appropriately selected in consideration of the shape inside the reaction chamber 31, that is, reaction efficiency and efficiency of using the space inside the reaction chamber 31, and the present disclosure is not specifically limited thereto.

The reaction chamber 31 is not specifically limited as long as it is generally used for composition of a BNNT, and may include a facility in which precursor blocks 2 may be arranged in an erect position in a line.

A gas supply pipe 33 (illustrated in FIG. 8A and 8B) may extend into the reaction chamber 31 and a reaction gas may be provided to at least a reaction zone in the reaction chamber 31 through the gas supply pipe 33. Accordingly, the gas supply pipe 33 may be longer than the reaction zone and may be disposed across the reaction zone in the reaction chamber 31.

In this case, a gas supply hole 331 that is diagonally open is formed on the surface of the gas supply pipe 33, so gas maybe supplied into the reaction chamber 31 through the gas supply pipe 33.

One or more gas supply holes 331 formed on the gas supply pipe 33 may be positioned in the reaction zone 311. Preferably, a plurality of gas supply holes 331 may be arranged with regular intervals in the longitudinal direction of the gas supply pipe 33 in the reaction zone 311.

The gas supply pipe 33 may extend in the longitudinal direction of the reaction chamber 31.

A reaction gas that is supplied into the reaction chamber 31 may be a mixture of nitrogen (N₂), ammonia (NH₃), hydrogen (H₂), etc., as described above. Further, since the molecular weights of nitrogen, ammonia, and hydrogen are respectively 28, 17, and 2 which are different, layer separation phenomenon in which the layers of the gases composing the reaction gas are separated may be generated.

When a reaction gas with separated layers is supplied, it influences the supply amount of the nitrogen element that is supplied to the precursor block so that the reaction gas may not be uniformly supplied, which may reduce the nitrification reaction efficiency of boron. Accordingly, it is required to prevent the layer separation phenomenon in the reaction gas, for example, by increasing the time of a heat treatment process in the reaction chamber 31 in order to provide a sufficient nitrogen element to the precursor block.

The gas supply pipe 33 supplies a reaction gas diagonally to the direction facing the holding rod 37, thereby being able to prevent the layer separation phenomenon.

In detail, the gas supply pipe 33 provides a reaction gas diagonally not providing the reaction gas directly to a holding rod holding precursor blocks 2. To this end, the gas supply pipe 33 has a gas supply hole 331 that is diagonally open. Since a reaction gas is provided through the gas supply hole 331 that is open at a predetermined angle, the reaction gas may generate a vortex while flowing along the inner wall of the reaction chamber 31. In this process, the reaction gas is rotated, mixed, and compounded, whereby it is possible to prevent layer separation phenomenon in the reaction gas.

As shown in FIGS. 8A and 8B, a gas supply hole 331 of a gas supply pipe 33 disposed in the reaction zone 311 of the reaction chamber 31 may provide a reaction gas at 45° diagonally from the straight line connecting the surface of the gas supply pipe 33 and the holding rod 37 as shown in FIG. 3.

As shown in FIGS. 8A, 8B, 9A, 9B, 10A, and 10B, two or more gas supply pipes 33 may be disposed in the reaction chamber 31. In this case, the gas supply pipes 33 may be disposed on the inner side of the reaction chamber 31 and arranged with regular intervals in the reaction chamber 31, respectively, so that a reaction gas discharged from their gas supply holes 331 may flow in one direction along the inner wall of the reaction chamber 31. Accordingly, the flow speed of a vortex generated by the discharged reaction gas turning around the inner side of the reaction chamber 31 may be relatively improved as compared with when one gas supply pipe 33 is provided.

Alternatively, when an even number of gas supply pipes 33 are disposed, they may be arranged in a pair at positions facing each other in the diameter direction of the reaction chamber 31. The gas supply holes 331 of the pair of gas supply pipes may be open in opposite directions so that a reaction gas discharged from the gas supply holes 331 may flow in one direction along the inner wall of the reaction chamber 31.

In this case, it is preferable that a plurality of gas supply holes 331 of the gas supply pipe 33 has the angle (hereafter, referred to as a “diagonal angle”) between the direction facing the holding rod and the diagonal opening directions of the gas supply holes 331 so that the reaction gas generates a stable vortex.

It is preferable that even though a plurality of gas supply pipes 33 is provided, the gas supply holes 331 of the gas supply pipes 33 have the same diagonal angle.

The nitrogen-containing reaction gas is mixed and compounded by the vortex in the reaction zone 311, and gases having different specific weights in the reaction gas may be mixed without layer separation. Accordingly, the supply amount of a nitrogen element that is supplied to the precursor block 2 becomes uniform, so the nitrification reaction efficiency of boron may be improved. That is, according to an embodiment of the present disclosure, the yield and productivity of BNNTs may be maximized.

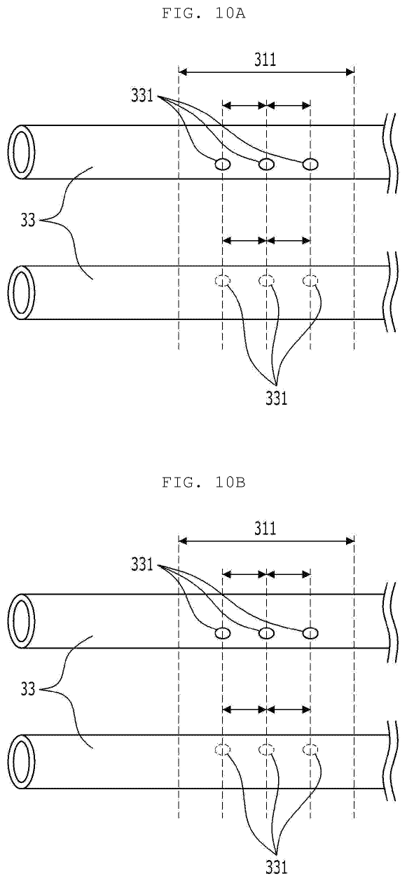

As shown in FIG. 10A, gas supply holes 331 formed on at least two gas supply pipes 33 may be positioned to face each other. Alternatively, as shown in FIG. 10B, gas supply holes 331 may be formed to be alternate to each other on gas supply pipes 33.

The gas supply pipe 33 may be connected to a gas supplier disposed outside the reaction chamber 31, and though not shown in the figures, the gas supplier may include a reaction gas storage tank and a gas supply pump.

According to another embodiment of the present disclosure, an exhaust pipe may extend into the reaction chamber 31. The exhaust pipe may be positioned at least out of the reaction zone of the reaction chamber 31. Accordingly, a reaction gas that has finished reacting may be discharged out of the reaction chamber 31, and an excessive increase of the internal pressure of the reaction chamber 31 may be prevented.

The exhaust pipe may be connected with a gas discharger disposed outside the reaction chamber 31, and though not shown in the figures, the gas discharge may include a valve for controlling the internal pressure of the reaction chamber 31, and an exhaust pump.

The reaction zone 311, as shown in FIGS. 3, 4A, and 4B, may be positioned substantially at the center of the reaction chamber 31 and the length of the reaction zone 311 may be adjusted in accordance with the capacity of the temperature adjuster of the reaction chamber 31.

According to an embodiment, it is possible to change the supply density of the reaction gas that is provided to the reaction zone 311. That is, it is possible to supply the reaction gas most to the middle portion, in which reaction is most actively generated, in the reaction zone 311, and it is possible to reduce the supply amount of the reaction gas that is supplied to the front and rear of the middle portion.

According to an embodiment of the present disclosure, a reaction module 38 may be moved in the longitudinal directions of the gas supply pipe 33 and the reaction chamber 31 to the heating zone 311 in the reaction chamber 31.

In this case, the gas supply pipe 33 may be disposed close to the supports 381 of the reaction module 38 to be able to provide a reaction gas close to the precursor block 2.

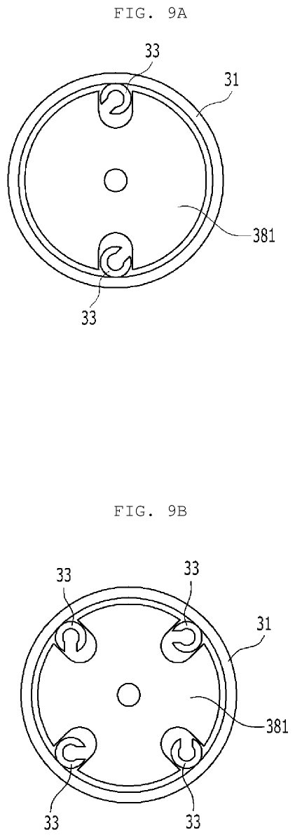

That is, as shown in FIG. 9A, the gas supply pipe 33 may be disposed between the supports 381 of the reaction module 38.

As shown in FIGS. 5 and 6, the supports 381 may have holders 383 to be disposed without interference with the gas supply pipe 33.

It is preferable that the holders 383 are formed to face each other at the supports 381 facing each other to pass the gas supply pipe 33.

The holders 383 may be grooves formed on the supports 381 or may be holes formed through the supports 381, but are not limited thereto.

The holders 383 may be positioned such that the gas supply pipe 33 and the supports 381 do not interfere with each other while the reaction module 38 is conveyed through a conveying path in the reaction chamber 31.

Although embodiments of the present disclosure were described above in detail, the right range of the present disclosure is not limited thereto, and various changes, equivalents, and modifications by those skilled in the art using the fundamental concept of the present disclosure defined in claims are also included in the right range of the present disclosure.

What is claimed is:

1. A method of producing a boron nitride nanotube, the method comprising steps of:
inserting several reaction modules each accommodating a holding rod disposed through at least one precursor block into a supply chamber disposed at a front end of a reaction chamber;
conveying a first set of N reaction modules of the several reaction modules inserted in the supply chamber to a reaction zone of the reaction chamber;
growing the boron nitride nanotube in the precursor block by operating the reaction zone for a predetermined time in the reaction chamber; and
conveying the first set of N reaction modules from the reaction chamber to a discharge chamber disposed at a rear end of the reaction chamber after the predetermined time passes,
wherein the conveying of the first set of N reaction modules of the several reaction modules inserted in the supply chamber to a reaction zone of the reaction chamber conveys a second set of N reaction modules of the several reaction modules from the supply chamber to the reaction chamber when conveying the first set of N reaction modules from the reaction chamber to the discharge chamber, and a conveying operation of the supply chamber is ended when all the several reaction modules are conveyed to the reaction chamber.

2. The method of claim 1, wherein the conveying the first set of N reaction modules of the several reaction modules inserted in the supply chamber to a reaction zone of the reaction chamber is accomplished by moving up the several reaction modules, which are vertically arranged, in the supply chamber in a longitudinal direction of the supply chamber.

3. The method of claim 1, wherein the conveying the first set of N reaction modules of the several reaction modules inserted in the supply chamber to the reaction zone of the reaction chamber is accomplished by circulating several reaction modules arranged on a circulation track along the circulation track in the supply chamber.

4. A method of producing a boron nitride nanotube, the method comprising steps of:
conveying a reaction module accommodating a holding rod disposed through at least one precursor block to a reaction zone of a reaction chamber; and
growing the boron nitride nanotube by reacting a nitrogen-containing reaction gas supplied from two or more gas supply pipes disposed in the reaction chamber with the precursor block,
wherein a gas supply hole that is diagonally open is formed on a surface of each of the gas supply pipes.

5. The method of claim 4, wherein an even number of the gas supply pipes are disposed in a pair at positions facing each other in a diameter direction of the reaction chamber, and the gas supply holes of a pair of the gas supply pipes are open in opposite directions.

6. The method of claim 4, wherein the gas supply holes are formed to be alternate to each other on the gas supply pipes.

7. The method of claim 4, wherein each of the gas supply holes is formed on each of the gas supply pipes and is disposed with regular intervals in a longitudinal direction of the gas supply pipes in the reaction zone.

8. An apparatus for producing a boron nitride nanotube, the apparatus comprising:
a reaction module accommodating a holding rod disposed through at least one precursor block;
a reaction chamber having a conveying path for conveying the reaction module and including a reaction zone in which a nitrogen-containing reaction gas is provided to the precursor block on the conveying path;
a supply chamber disposed at a front end of the reaction chamber, accommodating several reaction modules, and conveying a first set of N reaction modules of the several reaction modules to the reaction chamber; and
a discharge chamber disposed at a rear end of the reaction chamber,
wherein the reaction chamber conveys the first set of N reaction modules to the discharge chamber, and
the supply chamber conveys a second set of N reaction modules of the several reaction modules to the reaction chamber when the first set of N reaction modules are conveyed from the reaction chamber to the discharge chamber, and a conveying operation of the supply chamber is ended when all the several reaction modules are conveyed to the reaction chamber.

9. The apparatus of claim 8, wherein the supply chamber includes a lift having a plurality of reaction module holding units vertically arranged to mount the several reaction modules, and moving up the plurality of reaction module holding units in a longitudinal direction of the supply chamber.

10. The apparatus of claim 8, wherein the supply chamber includes a lift having a plurality of reaction module holding units arranged on a circulation track to mount the several reaction modules, and circulating the plurality of reaction module holding units along the circulation track.

11. An apparatus for producing a boron nitride nanotube, the apparatus comprising:
a reaction module accommodating a holding rod disposed through at least one precursor block;
a reaction chamber having a conveying path for conveying one or more of the reaction modules and including a reaction zone in which a nitrogen-containing reaction gas is provided to the precursor block on the conveying path; and
at least two gas supply pipes disposed along the conveying path,
wherein one or more gas supply holes that are diagonally open are formed on a surface of each of the gas supply pipes.

12. The apparatus of claim 11, wherein the several reaction modules each includes:
a pair of supports separably combined with the holding rod, having holders formed at positions respectively corresponding to the gas supply pipes, and facing each other; and
a housing formed between the pair of supports to accommodate the holding rod.

13. The apparatus of claim 11, wherein an even number of the gas supply pipes are disposed in a pair at positions facing each other in a diameter direction of the reaction chamber, and the gas supply holes of the pair of gas supply pipes are open in opposite directions.

14. The apparatus of claim 11, wherein the gas supply holes are formed to be alternate to each other on the gas supply pipes.

15. The apparatus of claim 11, wherein each of the gas supply holes is formed on each of the gas supply pipes and is disposed with regular intervals in a longitudinal direction of the gas supply pipes in the reaction zone.
